(19) United States
(12) Patent Application Publication
(10) Pub. No.: US 2007/0128872 A1
(43) Pub. Date: Jun. 7, 2007

(54) Polishing composition and polishing method

(76) Inventors: Yuji Itoh, Chiba (JP); Ayako Nishioka, Chiba (JP); Nobuo Uotani, Shiojiri-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 10/579,335

(22) PCT Filed: Nov. 15, 2004
(86) PCT No.: PCT/JP04/17317

§ 371 Date: May 15, 2006

Related U.S. Application Data
(60) Provisional application No. 60/523,684, filed on Nov. 21, 2003.

(30) Foreign Application Priority Data
Nov. 14, 2003 (JP) 2003-385253

(51) Int. Cl. H01L 21/44; H01L 21/302

(52) U.S. Cl. 438/691; 438/687

(57) ABSTRACT

As a polishing composition which allows high-speed polishing while dishing and erosion are prevented and the flatness of metal film is maintained, there is provided a polishing composition for polishing a metal film provided on a substrate having trenches such that the metal film fills the trenches, so as to provide a planarized surface, wherein the composition comprises water, a phosphate ester having a C≧6 carbon atom alkyl group in its molecule, and an etchant for the metal, and has a pH of 5 to 11.

### CROSS REFERENCE TO OTHER APPLICATION

This application is an application filed under 35 U.S.C. §111(a) claiming benefit pursuant to 35 U.S.C. §119(e)(1) of the filing date of the Provisional Application No. 60/523,684 filed on Nov. 21, 2003, pursuant to 35 U.S.C. §111(b).

### TECHNICAL FIELD

The present invention relates to a polishing composition for use in polishing a substrate, to a polishing method, and to a method for producing a substrate.

### BACKGROUND ART

Technical developments in ICs (integrated circuits) and LSI (large scale integration) have attained improvements in operation speed and degree of integration of these devices. For example, the performance of micro-processors and the capacity of memory chips have recently seen rapid improvements. Such improvements in device performance have in large measure been attained by virtue of development of micro-processing techniques. One typical example of micro-processing techniques is a chemical mechanical polishing method, which is a type of planarization technique. Chemical mechanical polishing is employed in planarization of an inter layer dielectric, a metal plug, and a metal wiring during a multi-layer wiring step.

Among these multi-wiring elements, in recent years, a metal wiring made of copper or copper alloy has been employed so as to prevent problematic delay of signals. Such copper or copper alloy wiring is fabricated by forming trenches in an inter layer dielectric in advance; if required, forming a thin barrier film formed of tantalum or tantalum nitride atop the trenches; and depositing copper or copper alloy through a technique such as the damascene method. During the above fabrication, excess copper or copper alloy remains on the inter layer dielectric. Thus, the wiring is formed while the excess copper or copper alloy is removed through polishing for planarization.

Meanwhile, a magnetic random access memory (MRAM) is one example of the magnetic recording media of interest. Regarding MRAM, there has been known a method for recording information to a specific bit in an element array. In the method, a bit-writing-in line and a word-writing-in line which cross each other while extending in the lengthwise and widthwise directions of an array, respectively, are provided, and information is written exclusively in an element located in the region where the two lines cross (see, for example, Japanese Patent Application Laid-Open (kokai) No. 10-116490). The metal wiring formed in the MRAM includes a conductor layer composed of aluminum or aluminum alloy, and copper or copper alloy; a ferromagnetic layer composed of nickel-iron (permalloy) and covering the conductor layer; and, if needed, a barrier film composed of a certain material (e.g., tantalum or tantalum nitride) and formed on the ferromagnetic layer. The metal wiring is formed through the damascene method, and excess portions of the conductor layer, the ferromagnetic layer, and the barrier film are removed through polishing performed in parallel, thereby providing a plane surface.

One possible approach for planarization with polishing is treatment by use of a polishing agent containing abrasive. However, when the treatment is performed only by use of a polishing agent, copper or copper alloy tends to be scratched due to moderate hardness thereof, considerably reducing yield of the device. Another possible approach is use of a polishing agent containing an etchant, which is capable of dissolving copper. However, if this approach is employed, trenches as well as protruded portions are etched, thereby causing dishing (i.e., a plane surface cannot be provided, and a portion of metal wiring is polished out).

Japanese Patent Application Laid-Open (kokai) No. 8-83780 discloses a polishing composition for polishing a metal film composed of copper or copper alloy with preventing occurrence of the above phenomenon. The composition contains hydrogen peroxide, benzotriazole, and aminoacetic acid, and if needed, abrasive. The document describes that benzotriazole contained in the composition forms a reaction-protective film with an oxidized metal film to allow mechanical polishing preferentially to protruded portions, thereby enhancing flatness, and to suppress dishing.

Japanese Patent Application Laid-Open (kokai) No. 9-55363 discloses a polishing composition containing 2-quinolinecarboxylic acid, which reacts with copper to form a copper complex having poor solubility in water and poor mechanical strength as compared with copper.

Japanese Patent Application Laid-Open (kokai) No. 2001-89749 discloses a polishing composition for a magnetic disk substrate for use in a memory hard disk, which composition contains (a) water, (b) at least one phosphate ester compound selected from the group consisting of polyoxyethylene alkyl ether phosphate and polyoxyethylene aryl ether phosphate, (c) at least one polishing accelerator selected from the group consisting of an inorganic acid, an organic acid, and a salt thereof other than the aforementioned phosphate ester compound (b), and (d) at least one polishing agent selected from the group consisting of aluminum oxide, silicon dioxide, cerium oxide, zirconium oxide, titanium oxide, silicon nitride, and manganese dioxide.

As the polishing composition as described in Japanese Patent Application Laid-Open (kokai) No. 8-83780 comprises benzotriazole having an strong anti-corrosive effect, polishing rate may detrimentally decrease. If the amount of benzotriazole is decreased in order to increase the polishing rate, a flat surface and dishing may be deteriorated.

The polishing composition as described in Japanese Patent Application Laid-Open (kokai) No. 9-55363 containing 2-quinolinecarboxylic acid is remarkably expensive and, therefore, it is considered that industrial use thereof is difficult.

The polishing composition as described in Japanese Patent Application Laid-Open (kokai) No. 2001-89749 is a polishing liquid for use in polishing a memory hard disk, and the document contains no description in relation to formation of metal wiring processed in the present invention.

In recent years, use of an inter layer dielectric formed of a low-κ material has been studied, in consideration of parasitic capacitance of copper wiring. In this connection, a variety of inorganic and organic low-κ materials have been developed, and in the future such low-κ materials will require a dielectric constant of less than 2.3. In order to attain such a dielectric constant, a porous low-κ material must be provided. Up-to-Date CMP Process and Material Technology (published by Technical Information Institute Co., Ltd., 2002), p. 133 discloses that such a porous low-κ material has poor mechanical strength and is problematically broken under conventionally employed CMP pressure, thereby imposing a requirement of polishing at low pressure. However, the aforementioned conventional technique was intended to be developed for high-pressure polishing, and high-speed polishing under low pressure has never been studied.

Furthermore, in recent years, the width of wiring tends to be narrower. In the case where fine wiring lines are present at high density, a barrier film and an inter layer dielectric are over-polished to form excavated portions (i.e., phenomenon so-called erosion). Similar to dishing, erosion causes a drop in resistance of wiring as well as short circuit of wiring. Thus, prevention of these phenomena is a problem to be solved.

Thus, an object of the present invention is to provide a polishing composition which allows high-speed polishing while dishing and erosion are prevented and the flatness of metal film is maintained. Another object of the invention is to provide a method for polishing metal film by use of the polishing composition. Still another object is to provide a method for producing a substrate comprising a step of planarizing the substrate by use of the polishing composition.

### SUMMARY OF THE INVENTION

The present inventors have carried out extensive studies in order to attain the above objects, and have found that the problems can be solved by a polishing composition for polishing a metal film provided on a substrate having trenches such that the trenches are filled with the metal film, so as to provide a planarized surface, which composition comprises water, a phosphate ester having a C≧6 alkyl group, and an etchant for the metal, and which has a pH of 5 to 11. The present invention has been accomplished on the basis of this finding.

Accordingly, the present invention is directed to the following [1] to [38].

[1] A polishing composition for polishing a metal film provided on a substrate having trenches such that the metal film fills the trenches, so as to provide a planarized surface, wherein the composition comprises water, a phosphate ester having a C≧6 carbon atom alkyl group in its molecule, and an etchant for the metal, and has a pH of 5 to 11.

[2] The polishing composition according to [1] above, wherein said phosphate ester is a phosphate ester having a C6 to C22 alkyl group in its molecule.

[3] The polishing composition according to [1] or [2] above, wherein the content of said phosphate ester is in a range of 0.0001 to 2 mass %.

[4] The polishing composition according to any one of [1] to [3], wherein said etchant comprises an acid and/or a base, and an oxidizing agent.

[5] The polishing composition according to [4] above, wherein the content of said an acid and/or a base is in range of 0.01 to 10 mass %.

[6] The polishing composition according to [4] above, wherein the content of said oxidizing agent is in range of 0.01 to 30 mass %.

[7] The polishing composition according to any one of [1] to [6] above, which further comprises abrasive.

[8] The polishing composition according to [7] above, wherein the content of said abrasive is in range of 30 mass % or less.

[9] The polishing composition according to any one of [1] to [8] above, which further comprises a surfactant.

[10] The polishing composition according to [9] above, wherein the content of said surfactant is in range of 5 mass % or less.

[11] The polishing composition according to any one of [1] to [10], which further comprises a compound having two or more azole moieties in its molecule.

[12] The polishing composition according to [11] above, wherein the content of said compound having two or more azole moieties in its molecule is in range of 0.001 to 1 mass %.

[13] The polishing composition according to any one of [1] to [12] above, which further comprises an amino acid.

[14] The polishing composition according to [13] above, wherein the content of said amino acid is in range of 0.001 to 10 mass %.

[15] The polishing composition according to any one of [1] to [14] above, which further comprises a compound having one azole moiety in its molecule.

[16] The polishing composition according to [15] above, wherein the content of said compound having one azole moiety in its molecule is in range of 0.001 to 5 mass %.

[17] The polishing composition according to any one of [1] to [16] above, which further comprises a fatty acid having a C≧6 atom alkyl group in its molecule.

[18] The polishing composition according to [17] above, wherein the content of said fatty acid having a six or more carbon atom alkyl group in its molecule is in range of 0.001 to 5 mass %.

[19] The polishing composition according to any one of [4] to [18] above, where said acid is an inorganic acid or carboxylic acid.

[20] The polishing composition according to [19] above, wherein said inorganic acids is at least one species selected from the group consisting of sulfuric acid, phosphoric acid, phosphonic acid, and nitric acid.

[21] The polishing composition according to [19] above, wherein said carboxylic acids is at least one species selected from the group consisting of formic acid, acetic acid, propionic acid, butyric acid, valeric acid, 2-methylburyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid (hydroxyacetic acid), salicylic acid, glyceric acid, oxalic acid, malonic acid, succinic acid, glutaric acid, adipic acid, pimelic acid, maleic acid, phthalic acid, malic acid, tartaric acid, citric acid, lactic acid, nicotic acid, quinaldinic acid, and anthranilic acid.

[22] The polishing composition according to any one of [1] to [21] above, wherein said base is at least one species selected from the group consisting of ammonia; sodium hydroxide; potassium hydroxide; potassium carbonate; potassium hydrogencarbonate; ammonium hydrogencarbonate; alkylmonoamines; allylamine; 2-ethylhexylamine; cyclohexylamine, benzylamine, and furfurylamine; monoamines having a hydroxyl group; diamines; and polyamines.

[23] The polishing composition according to any one of [4] to [22] above, wherein said oxidizing agent is at least one species selected from the group consisting of oxygen, hydrogen peroxide, ozone, alkyl peroxides, peracids, permanganate salts, persulfate salts, polyoxo acids, hypochlorite salts, and periodate salts.

[24] The polishing composition according to any one of [8] to [23] above, wherein said abrasive is formed of at least one species selected from the group consisting of silica, cerium oxide, aluminum oxide, aluminum hydroxide, titanium dioxide, and organic abrasive.

[25] The polishing composition according to any one of [10] to [24] above, wherein said surfactant is at least one species selected from the group consisting of anionic surfactants, cationic surfactants, nonionic surfactants, and ampholytic surfactants.

[26] The polishing composition according to any one of [10] to [25] above, wherein said surfactant is an alkylaromatic-sulfonic acid or a salt thereof.

[27] The polishing composition according to any one of [12] to [26] above, wherein said compound having two or more azole moieties in its molecule is an azole polymer having a vinyl group.

[28] The polishing composition according to [12] to [27] above, wherein said compound having two or more azole moieties in its molecule is a polymer having a mass average molecular mass of 2,000 to 500,000.

[29] The polishing composition according to any one of [13] to [28] above, wherein said amino acid is at least one species selected from the group consisting of glycine, alanine, β-alanine, 2-aminobutyric acid, norvaline, valine, leucine, norleucine, isoleucine, allo-isoleucine, phenylalanine, proline, sarcosine, ornithine, lysine, taurine, serine, threonine, allo-threonine, homoserine, tyrosine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxy-lysine, creatine, kynurenine, histidine, 1-methyl-histidine, 3-methyl-histidine, ergothioneine, and tryptophan.

[30] The polishing composition according to any one of [15] to [29] above, wherein said compound having one azole moiety in its molecule is at least one species selected from the group consisting of benzimidazole-2-thiol, 2-[2-(benzothiazolyl)]thiopropionic acid, 2-[2-(benzothiazolyl)]thiobutyric acid, 2-mercaptobenzothiazole, 1,2,3-triazole, 1,2,4-triazole, 3-amino-1H-1,2,4-triazole, benzotriazole, 1-hydroxybenzotriazole, 1-dihydroxypropylbenzotriazole, 2,3-dicarboxypropylbenzotriazole, 4-hydroxybenzotriazole, 4-carboxyl-1H-benzotriazole, 4-methoxycarbonyl-1H-benzotriazole, 4-butoxycarbonyl-1H-benzotriazole, 4-octyloxycarbonyl-1H-benzotriazole, 5-hexylbenzotriazole, N-(1,2,3-benzotriazolyl-1-methyl)-N-(1,2,4-triazolyl-1-methyl)-2-ethylhexylamine, tolyltriazole, naphthotriazole, benzimidazole, tetrazole, hydroxybenzotriazole, and carboxybenzotriazole.

[31] A composition which forms the polishing composition as set forth in any one of [1] to [30] above by dilution.

[32] A kit comprising a plurality of compositions, which forms the polishing composition as set forth in any one of [1] to [30] above by (i) mixing or (ii) mixing and diluting said plurality of compositions.

[33] A polishing method, characterized by comprising polishing, by use of the polishing composition as recited in any one of [1] to [30] above, a metal film provided on a substrate having trenches such that the metal film fills the trenches so as to provide a planarized surface.

[34] The polishing composition according to [33] above, wherein said metal film is of copper or an alloy containing copper.

[35] The polishing composition according to [34] above, wherein said metal film is stacked with at least two layers: a barrier layer and a metal wiring layer.

[36] The polishing composition according to [35] above, wherein said barrier layer is formed of at least one species selected from the group consisting of tantalum, tantalum alloy, tantalum nitride, titanium, and titanium alloy.

[37] A method for using the composition as set forth in [31] above.

[38] A method for using the kit as set forth in [32] above as a composition for transportation or storage.

### BRIEF DESCRIPTION OF THE DRAWINGS

FIG. 1 shows a cross-section of a pattern wafer for measuring dishing in Examples.

FIG. 2 is a cross-section of a wafer to show dishing in Examples.

FIG. 3 is a cross-section of a wafer to show erosion in Examples.

### BEST MODES FOR CARRYING OUT THE INVENTION

Modes for carrying out the present invention will next be described in detail.

The present invention is directed to a polishing composition for polishing a metal film provided on a substrate having trenches such that the trenches are filled with the metal film, so as to provide a planarized surface. The polishing composition comprises water, a phosphate ester having a C≧6 alkyl group in its molecule, and an etchant for the metal, and has a pH of 5 to 11.

The phosphate ester having a C≧6 alkyl group in its molecule contained in the polishing composition of the present invention reduces dishing.

No particular limitation is imposed on the structure of the phosphate ester used in the present invention, so long as the ester has a C≧6 alkyl group. Thus, the phosphate ester may has, in its molecule, a group other than the alkyl group such as an oxyalkylene chain, a phenylene chain, or a phenyl group. The phosphate ester may be monoester, diester, or triester. Phosphate is preferably sufficiently soluble or dispersible in a polishing composition and the preferred number of carbon atoms thereof is 6 to 22.

The phosphate ester may be in the salt form such as a potassium salt or an ammonium salt. The phosphate ester may be a commercial product, or may be synthesized from a compound having a hydroxyl group through a conventional method.

Examples of the aforementioned phosphate ester include octyl phosphate, decyl phosphate, lauryl phosphate, myristyl phosphate, cetyl phosphate, stearyl phosphate, secondary alkyl (av. C13) phosphate, 2-ethylhexyl phosphate, oleyl phosphate, monostearyl glyceryl ether phosphate, monocetyl glyceryl ether phosphate, monooleyl glyceryl ether phosphate, isostearyl glyceryl ether phosphate, polyoxyethylene octyl ether phosphate, polyoxyethylene decyl ether phosphate, polyoxyethylene lauryl phosphate, polyoxyethylene myristyl ether phosphate, polyoxyethylene cetyl ether phosphate, polyoxyethylene stearyl ether phosphate, polyoxyethylene secondary alkyl (av. C13) ether phosphate, polyoxyethylene 2-ethylhexyl ether phosphate, polyoxyethylene 2-oleyl ether phosphate, and polyoxyethylene nonylphenyl ether phosphate. Of these, C8 to C18 alkyl phosphates such as octyl phosphate, lauryl phosphate, and stearyl phosphate; and phosphate esters having an oxyethylene chain such as polyosyethylene lauryl ether phosphate and polyoxyethylene secondary alkyl (av. C13) ether phosphate are preferred.

The above phosphate esters having a C≧6 alkyl group may be incorporated into the composition of the present invention singly or in combination of two or more species. The amount of the phosphate ester content is preferably 0.0001 to 2 mass %, more preferably 0.001 to 1 mass %. When the amount is small, effect of preventing dishing is not fully attained, whereas when the amount is large, dishing may be prevented but it is difficult to practically use it for an application where a high polishing rate is required the effect and the stability of polishing liquid may be impaired.

The etchant is incorporated into the polishing composition of the present invention in order to promote polishing and perform reliable polishing. The etchant may be any one having a capability of etching the metal material to be polished and the particular composition of the etchant is appropriately controlled depending on the metallic species to be polished. For example, for polishing copper, an etchant containing an acid and/or a base as well as an oxidizing agent may be mentioned.

Examples of the above acid include inorganic acids such as sulfuric acid, phosphoric acid, phosphonic acid, and nitric acid; and carboxylic acids such as formic acid, acetic acid, propionic acid, butyric acid, valeric acid, 2-methylburyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid (hydroxyacetic acid), salicylic acid, glyceric acid, oxalic acid, malonic acid, succinic acid, glutaric acid, adipic acid, pimelic acid, maleic acid, phthalic acid, malic acid, tartaric acid, citric acid, lactic acid, nicotic acid, quinaldinic acid, and anthranilic acid.

Examples of the above base include ammonia; sodium hydroxide; potassium hydroxide; potassium carbonate; potassium hydrogencarbonate; ammonium hydrogencarbonate; alkylmonoamines such as methylamine, ethylamine, propylamine, isopropylamine, butylamine, isobutylamine, t-butylamine, amylamine, allylamine, 2-ethylhexylamine, cyclohexylamine, benzylamine, and furfurylamine; monoamines having a hydroxyl group such as; o-aminophenol, ethanolamine, 3-amino-1-propanol, and 2-amino-1-propanol; diamines such as ethylenediamine, diethylenetriamine, triethylenetetramine, tetraethylenepentamine, pentaethylenehexamine, o-phenylenediamine, trimethylenediamine, 1,2-diaminopropane, 2,2-diamino-di-n-propylamine, 2-methyl-2-(2-benzylthioethyl)ethylenediamine, 1,5-diamino-3-pentanol, 1,3-diamino-2-propanol, xylenediamine, and bisaminopropylpolyalkylene ether; and polymers having a basic functionality such as polyallylamine and polyethyleneimine. Of these, ammonia and ethylene diamine are preferred.

These acids and bases may be used singly or in combination of a plurality of species. Therefore, a salt formed from the acid and base as described above may be used. No particular limitation is imposed on the total amount of acids and bases so long as the pH of the composition falls within a range of 5 to 11. However, the amount is preferably 0.01 to 10 mass %. When the amount is small, an appropriate polishing rate cannot be attained, whereas when the amount is excessively large, etching rate with respect to the target metal or the target alloy of the metal may excessively increase, thereby failing to obtain a flat surface and prevent dishing. When the pH is lower than 5 or higher than 11, stability of polishing liquid may be impaired.

Examples of the aforementioned oxidizing agent include oxygen, ozone, hydrogen peroxide, alkyl peroxides (e.g., t-butyl hydroperoxide and ethylbenzene hydroperoxide), peracids (e.g., peracetic acid and perbenzoic acid), permanganate salts (e.g., potassium permanganate), periodate salt (e.g., potassium periodate), persulfate salts (e.g., ammonium persulfate and potassium persulfate), polyoxo acids, and hypochlorite salts (e.g., potassium hypochlorite). Among these oxidizing agents, hydrogen peroxide, persulfate salts and hypochlorates, which can be simply handled, are preferred.

The amount of the oxidizing agent is not particularly specified because a different appropriate range exists for each case depending on a matallic spieces to be polished or a pH of a solution or the like. However, it is preferably 0.01 to 30 mass % with respect to the polishing composition, more preferably 0.05 to 20 mass %, particularly preferably 0.1 to 10 mass %. When the amount is small or larger, it may be potentially difficult to attain a sufficient polishing rate. A large amount thereof may cause economically disadvantageous treatment of waste of the polishing composition.

The polishing composition of the present invention can may be employed without use of an abrasive. However, in order to sufficiently increase a polishing rate, an abrasive may be incorporated into the composition. Examples of the abrasive include silica grains, cerium oxide grains, aluminum oxide grains, aluminum hydroxide grains, titanium dioxide grains, and organic abrasive. These abrasives may be used singly or in combination of two or more species. Compound abrasive prepared from two or more members of the above grain components may also be employed. The abrasive incorporated into the polishing composition in an amount of preferably 30 mass % or less, more preferably 20 mass % or less, particularly preferably 10 mass % or less. An excessively large amount thereof causes sever dishing and increases scratches.

Through incorporation of a surfactant into the polishing composition of the present invention improves dishing.

In the present invention, any of anionic surfactants, cationic surfactants, and nonionic surfactants may be employed. Examples of the cationic surfactants include aliphatic amines or salts thereof and aliphatic ammonium salts. Examples of the anionic surfactants include fatty acid soap; alkyl ether carboxylic acids and salts thereof; sulfonic acid compounds such as α-olefinsulfonic acids and salts thereof, alkylbenzenesulfonic acids and salts thereof, and alkylnaphthalenesulfonic acids and salts thereof; and sulfate ester compounds (e.g., higher alcohol sulfate esters, and alkyl(phenyl) ether sulfuric acids and salts thereof). Examples of the non-ionic surfactants include ester species (e.g., polyoxyethylene alkyl ethers), ether-ester species (e.g., glycerin ester polyoxyethylene ethers), and ester species (e.g., polyethylene glycol fatty acid esters, glycerin esters, and sorbitan esters). Of these, sulfonate compound surfactants are preferred, with alkylaromatic sulfonic acids having an alkyl group and salts thereof being more preferred.

These surfactants may be used singly or in combination of a plurality of species.

The surfactant is incorporated into the polishing composition in an amount of preferably 5 mass % or less, more preferably 0.0001 to 1 mass %, particularly preferably 0.0001 to 0.5 mass %.

The polishing composition of the present invention may further contain a compound having two or more azole moieties in its molecule, the compound effectively reducing dishing.

The compound having two or more azole moieties in its molecule employed in the present invention may be produced through any of a variety of methods. Some azole compounds such as imidazoles, triazoles, tetrazoles, and thiazoles include compounds having a reactive substituent such as a hydroxyl group, a carboxyl group, or an amino group. Examples of such azole compounds include 4-carboxyl-1H-benzotriazole, 4-hydroxybenzotriazloe, and 2-aminoimidazole. The carboxyl group reacts with polyhydric alcohol or polyvalent amine, to thereby form the corresponding ester or amide. When a polyhydric alcohol or a polyvalent amine having two or more functionalities is used, a compound having two or more azole moieties in its molecule can be produced. Alternatively, an azole compound having a hydroxyl group or an amino group is reacted with a compound having a reactive site with respect to the hydroxyl group or amino group, to thereby produce a compound having two or more azole moieties in its molecule.

Alternatively, a compound having two or more azole moieties may be produced through polymerization of an azole compound having a vinyl group. Examples of the vinyl-group-containing azole compound include 1-vinylimidazole, 2-[3-(2H-benzotriazol-1-yl)-4-hydroxyphenyl]ethyl methacrylate.

Among compounds having two or more azole moieties, compounds produced by polymerizing an azole compound having a vinyl group are preferred as they have advantages of being easy to produce and easy to control the number of azole in one molecule and the molecular mass. The polymer may be a homopolymer or a copolymer with another vinyl compound.

Examples of the vinyl compound which can copolymerize with an azole compound having a vinyl group include acrylic acid, methacrylic acid, methyl acrylate, methyl methacrylate, acrylamide, N-isopropylacrylamide, diacetoneacrylamide, N-t-octylacrylamide, N-vinylacetamide, N-vinylformamide, acryloylmorpholine, N-vinylpyrrolidone, vinyl acetate, and styrene.

The above vinyl compounds are generally polymerized through radical polymerization in an aqueous solution or an organic solvent. Radical polymerization is typically performed in the presence of an initiator such as azobisisobutyronitrile, and a chain transfer agent such as dodecylmercaptan, trimethylolpropanetris(3-mercaptopropionate), mercaptoethanol, or α-methylstyrene dimer may also be used to control molecular mass of the product.

The thus-produce polymer employable in the present invention has a mass average molecular mass of preferably 300 to 5,000,000, more preferably 1,000 to 1,000,000, particularly preferably 2,000 to 500,000.

The compound having two or more azole moieties in its molecule employable in the present invention may be incorporated singly or in combination of two or more species into the polishing composition. The amount thereof is preferably 0.001 to 1 mass %, more preferably 0.001 to 0.5 mass %, particularly preferably 0.001 to 0.1 mass %. When the amount is small, dishing prevention is insufficiently attained, whereas when the amount is large, the effect commensurate with addition cannot be attained and, in some cases, aggregation of abrasive in the polishing composition may be promoted.

Examples of the amino acid employed in the present invention include glycine, alanine, β-alanine, 2-aminobutyric acid, norvaline, valine, leucine, norleucine, isoleucine, allo-isoleucine, phenylalanine, proline, sarcosine, ornithine, lysine, taurine, serine, threonine, allo-threonine, homoserine, tyrosine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxy-lysine, creatine, kynurenine, histidine, 1-methyl-histidine, 3-methyl-histidine, ergothioneine, and tryptophan. Of these, glycine, alanine, leucine, valine, histidine, and serine are preferred.

These amino acids may be used singly or in combination of two or more species. The amino acids are incorporated into the polishing composition in an amount of preferably 0.001 to 10 mass %, more preferably 0.001 to 5 mass %, particularly preferably 0.001 to 2 mass %. When the amount is excessively large, stability of polishing liquid may be impaired.

Further incorporation of a compound having one azole moiety in its molecule into the polishing composition of the present invention has an effect of reducing dishing.

Examples of the compound having one azole moiety in its molecule include benzimidazole-2-thiol, 2-[2-(benzothiazolyl)]thiopropionic acid, 2-[2-(benzothiazolyl)]thiobutyric acid, 2-mercaptobenzothiazole, 1,2,3-triazole, 1,2,4-triazole, 3-amino-1H-1,2,4-triazole, benzotriazole, 1-hydroxybenzotriazole, 1-dihydroxypropylbenzotriazole, 2,3-dicarboxypropylbenzotriazole, 4-hydroxybenzotriazole, 4-carboxyl-1H-benzotriazole, 4-methoxycarbonyl-1H-benzotriazole, 4-butoxycarbonyl-1H-benzotriazole, 4-octyloxycarbonyl-1H-benzotriazole, 5-hexylbenzotriazole, N-(1,2,3-benzotriazolyl-1-methyl)-N-(1,2,4-triazolyl-1-methyl)-2-ethylhexylamine, tolyltriazole, naphthotriazole, benzimidazole, and tetrazole. Of these, benzotriazole, tolyltriazole, hydroxybenzotriazole, carboxybenzotriazole, benzimidazole, tetrazole and histidine are preferred.

These compounds may be used singly or in combination of two or more species. The compounds are incorporated into the polishing composition in an amount of preferably 0.001 to 5 mass %, more preferably 0.001 to 2 mass %, particularly preferably 0.001 to 0.5 mass %. When the amount is excessively large, stability of polishing liquid may be impaired.

The polishing composition of the present invention contains a fatty acid having a C≧6 alkyl group, the fatty acid effectively reducing dishing.

The fatty acid having a C≧6 alkyl group is not particularly limited in its structure such as number of carbon atoms, number of carboxyl groups, presence or absence of other functionality and branches as far as it can be dissolved or dispersed in a polishing composition. The number of carbon atoms is preferably in a range of 6 to 22. Examples of the fatty acid having a C≧6 alkyl group include octanoic acid, decanoic acid, lauric acid, myristic acid, palmitic acid, stearic acid, isostearic acid, 12-hydroxystearic acid, sebacic acid, oleic acid, and linoleic acid.

These acids may be used singly or in combination of two or more species. The acids are incorporated into the polishing composition in an amount of preferably 0.001 to 5 mass %, more preferably 0.001 to 2 mass %, particularly preferably 0.001 to 0.5 mass %. When the amount is excessively large, stability of polishing liquid may be impaired.

The polishing composition of the present invention is, in general, preferably used at about room temperature as a temperature control device is not required. However, the temperature of the polishing composition may be modified and supplied to a polishing machine for the purpose of, for example, control of polishing rate. The temperature range is preferably in a range of 0 to 100° C., more preferably 10 to 50° C., particularly preferably 15 to 40° C. When the temperature is too low, polishing rate cannot be increased, and the polishing liquid may be solidified at a temperature below 0° C., whereas when the temperature is excessively high, there is a possibility that a undesired side reaction may occur.

The amount of the polishing composition supplied to a polishing machine is determined in accordance with the dimensions of the polishing machine employed and the wafer to be polished. When an 8-inch wafer is polished, an amount of 10 to 1,000 mL/min may be preferably employed. The amount is more preferably 50 to 500 mL/min, particularly preferably 100 to 400 mL/min. The amount of supplied composition may be changed in the course of polishing. For example, the amount of supplied composition may be increased or decreased at a half time of polishing time period.

In the polishing method employing the polishing composition of the present invention, a workpiece (substrate having a metal film) to be polished is pressed against a polishing pad affixed to a platen. While the polishing composition of the present invention is fed between the polishing pad and the substrate, relative rotation between the platen and the substrate is effected, thereby polishing the workpiece. In this case, any conventional polishing machine having a holder for holding a semiconductor substrate and a platen onto which a polishing pad is affixed may be employed. The rotation speed of the platen varies considerably depending on the structure and dimensions of the polishing machine employed and, therefore, the peroipheral speed cannot be predetermined definitively. However, in a case where a common polishing machine is used, the rotation speed is preferably 10 to 500 m/min, more preferably 20 to 300 m/min, particularly preferably 30 to 150 m/min. In order to perform uniform polishing of the substrate through rotation of the platen the substrate must be rotated. The substrate is rotated at a speed almost equal to that of the platen and, in some cases, the rotation speed may be slightly modified (accelerated or retarded) so as to accomplish uniform polishing. The substrate is pressed against the polishing pad by means of a holder for holding the substrate. The pressure may be preferably 0.1 to 100 kPa. The pressure cannot be predetermined definitively, because when the rotation speed of the surface-substrate is high, the pressure is prone to decrease. However, the pressure is more preferably 0.1 to 80 kPa, particularly preferably 0.1 to 50 kPa. These polishing conditions may be changed in the course of polishing. For example, the rotation speed may be increased or decreased at a half time of polishing time period.

The polishing pad employed in the present invention is generally made of non-woven fabric or polyurethane foam. Most polishing pads have grooves so as to accelerate polishing and to facilitate discharge of a polishing slurry. Examples of such grooved polishing pads include a polishing pad having grooves in the lengthwise and widthwise directions (XY groove) and a polishing pad having concentric grooves (K groove). The polishing composition of the present invention is applicable to any of these polishing pads. Polishing pads are generally dressed by means of a diamond dresser so as to prevent clogging and to perform reliable polishing. In the present, any conventionally known dressing method may be employed.

The polishing composition of the present invention is continuously supplied onto the polishing pad affixed on the platen by use of a pump or a similar apparatus. The polishing composition to be supplied may be in the form of a single liquid containing all ingredients. Alternatively, the composition may be supplied in a divided manner in the form of a plurality of liquid components (e.g., hydrogen peroxide solution and other solutions; a polishing solution composed mainly of abrasive and a solution comprising other components; or the like) in consideration of stability of the polishing liquid. The divided solutions may be combined to form a single solution just before supplying to a polishing cloth. In such a case, a plurality of lines may be connected to a single line, or a mixing device such as a reservoir for mixing a plurality of polishing solutions may be used. Alternatively, respective polishing solutions may be supplied through separate lines to a polishing cloth. The flow rates of respective solutions may be changed in the course of polishing. For example, when a combination of two solutions are used, the flow rate of one of the dropwise fed two solutions is increased or decreased at a half time of polishing time period.

The polishing composition of the present invention may be stored in the form of a plurality of separate compositions and/or in the form of a thick composition during transportation or storage, considering convenience of handling, such as stability of solutions. For example, the polishing composition may be divided into an oxidant solution and a remaining solution. When an abrasive is used, a solution mainly composed of the abrasive and a remaining solution. Also, the polishing composition may be prepared as a thicker composition condensed than when used, which is used after diluting with water, etc. to a concentration appropriate for polishing. The plurality of thus divided compositions may be combined to constitute a kit which forms the polishing composition of the present invention optionally by mixing and diluting them.

The metal film to be preferably polished by use of the polishing composition of the present invention is provided on a surface of a substrate having trenches such that the trenches are filled with the metal film. Through planarization polishing of the metal film, a wiring layer built in the trenches is obtained. A barrier layer may be inserted between the metal wiring layer and the substrate. In this case, the barrier layer is generally polished together with the metal film. Examples of metals forming the metal film include aluminum, copper, iron, tungsten, nickel, tantalum, platinum group metals (e.g., ruthenium and platinum), and alloys thereof. Examples of metals forming the barrier layer include elemental metals such as tantalum and titanium and metal compounds such as tantalum nitride and titanium nitride. In a preferred mode, the metal film covers wiring portions of a multilayer wiring portion or a wiring portion, and is provided on a surface of a substrate having trenches such that the trenches are filled with the metal film. In a more preferred mode, the metal film serving as a wiring portion of the multilayer wiring portion is formed of copper or copper alloy, or iron or iron alloy. The step will be next be described in more detail, by reference to an example of formation of a wiring on a device element. First, grooves and openings for wiring are provided in an inter layer dielectric affixed onto a substrate, and a thin barrier layer is formed on the insulating film. Subsequently, a metal (e.g., copper) wiring layer is formed, through plating or a similar method, such that the trenches and openings are filled with the metal wiring layer. The metal layer is polished and, if required, the barrier layer and the inter layer dielectric are planarization-polished, to thereby form a substrate having a flat metal film on a surface thereof. The barrier layer is preferably formed of tantalum, tantalum-containing alloy, titanium, titanium-containing alloy, or tantalum nitride.

In the present invention, the inter layer dielectric includes an inorganic inter layer dielectric having high silicon content such as silicon oxide film, hydroxysilsesquioxane (HSQ), or methylsilsesquioxane (MSQ), and an organic inter layer dielectric such as a benzocyclobutene film. These films may incorporate pores, to thereby serve as low-dielectric-constant inter layer dielectrics.

The wiring method employed in MRAMs will next be described. The metal wiring provided in an MRAM includes a conductor layer composed of aluminum or aluminum alloy, and copper or copper alloy; and a ferromagnetic layer composed of nickel-iron (permalloy) and covering the conductor layer. If needed, a thin barrier film composed of a certain material (e.g., tantalum or tantalum nitride) is formed on the ferromagnetic layer. The metal wiring is formed through the damascene method, and excess portions of the conductor layer, the ferromagnetic layer, and the barrier film are removed through polishing performed in parallel, thereby providing a planar surface.

### EXAMPLES

The present invention will next be described in more detail by way of examples, which should not be construed as limiting the invention thereto.

<Wafer>

Blanket: Silicon wafer uniformly coated with copper film and tantalum film

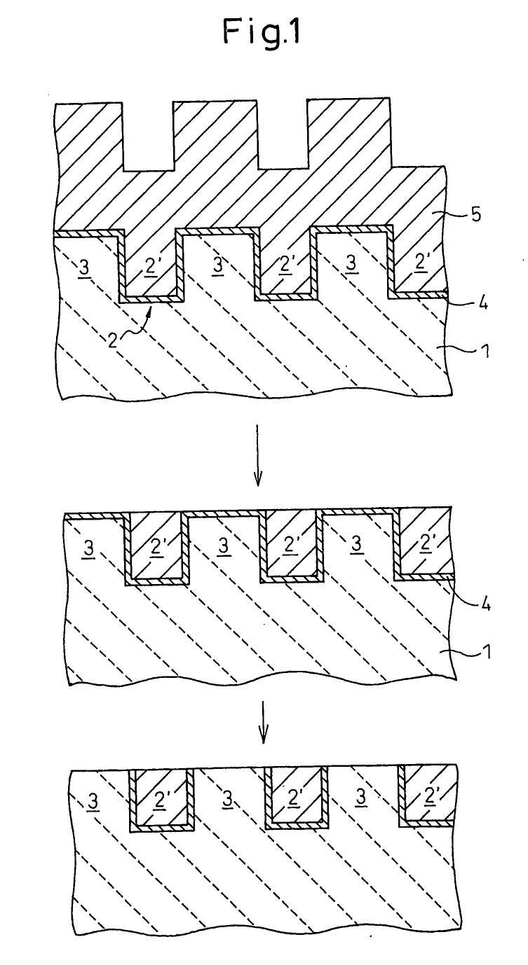

Pattern: As shown in FIG. 1. A silicon wafer 1 for forming a copper wiring patter thereon having grooves 2 (depth: 500 nm) arranged at a line 2′/space 3 ratio of 100 μm/100 μm (or 9 μm/1 μm). The wafer is coated with a barrier film 4 (25 nm) made of tantalum, and the entire surface is coated with a copper film 5 (1,000 nm).

<Polishing of Wafer Cut to 4×4 cm Pieces>

Relative speed of platen to substrate: 70 m/min

Polishing pad: IC 1400 (Product of Rodel Nitta)

Polishing composition feed rate: 13 mL/min

Pressing force: 15 kPa

<Etching Test>

Etching rate (per minute) was obtained by immersing each copper sheet piece (2 cm×2 cm) in the respective polishing composition and measuring the amount of loss.

<Evaluation of Polishing Characteristics>

Measurement of step (depth): The depth was determined by use of a probe-type step meter.

Thickness measurement (blanket copper and tantalum film): Each thickness was determined through measurement of sheet resistance.

Thickness measurement (copper pattern film): The thickness was determined through measurement of sheet resistance of an unpatterned portion in the vicinity of the site to be evaluated.

Determination of polishing rate: Copper film thickness and barrier film thickness were determined before and after polishing, through measurement of electrical resistance. The difference was divided by polishing time.

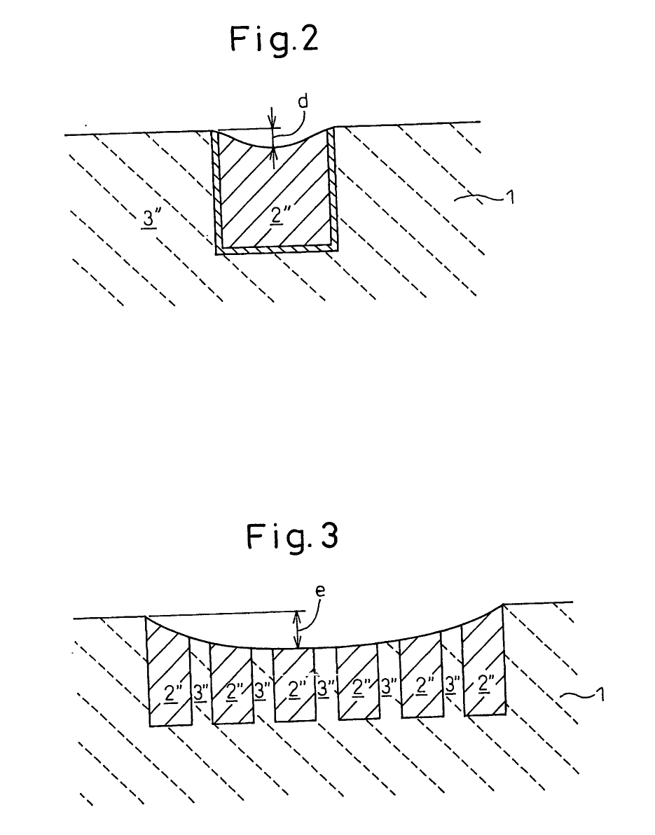

Evaluation of dishing: The polishing rate employed was determined by polishing a pattered wafer such that copper film was left at a thickness of about 300 nm. Through employment of the polishing rate, each wafer was polished for a certain period of time so as to polish the copper film for a thickness of 1,500 nm (50% over-polishing vs. initial copper film thickness). As shown in FIG. 2, a step “d” between the height of a 100 μm space 3″ and that of a 100 μm line portion 2″ was employed as an index for evaluating dishing.

Erosion measurement: The polishing rate employed was determined by polishing a patterned wafer such that copper film was left at a thickness of about 300 nm. Through employment of the polishing rate, each wafer was polished under certain conditions; i.e., for a certain period of time so that the copper film was over-polished at a rate of 50% (calculated) vs. the initial thickness. As shown in FIG. 3, a loss “e” of the barrier film and the inter layer dielectric at a space portion at a 9 μm/1 μm (line/space) was employed as an index for evaluating erosion.

### Examples 1 to 11, and Comparative Examples 1 to 3

The compositional proportions of the polishing compositions are shown in Tables 1-1 to 1-5.

In Tables 1-1 to 1-5, polyoxyethylene sec-alkyl ether phosphate was prepared by phosphating an alcohol species (average 3 mol ethylene oxide adduct of C13 (av.) secondary alcohol). Polyoxiethylene octyl ether phosphate, polyoxiethylene oleyl phosphate and polyoxiethylene rauryl phosphate are similar phosphates. DBS, APS, and BTA refer to dodecyl benzenesulfonic acid, ammonium persulfate, and benzotriazole, respectively.

Colloidal silica A employed had a primary particle size of 30 to 40 nm and a secondary particle size of 70 nm. Colloidal silica B employed had a primary particle size of 65 to 75 nm and a secondary particle size of 120 nm. Colloidal silica C employed had a primary particle size of 95 to 105 nm and a secondary particle size of 210 nm. VPI55K18P (product of BASF), which was employed as a compound having two or more azole moieties, is a 1:1 copolymer of 1-vinylimidazole and 1-vinylpyrrolidone. Through GPC measurement, the copolymer was found to have a mass average molecular mass (as reduced to polyethylene glycol) of 5,000 and a number average molecular mass of 2,300. SokalanHP56 (product of BASF) was a copolymer composed of 1-vinylimidazole and 1-vinylpyrrolidone at a ratio of 1:1. Through GPC measurement, the product was found to have a mass average molecular mass (as reduced to polyethylene glycol) of 18,000 and a number average molecular mass of 6,600. Compounds A, B, C, D and E were synthesized through the following procedure.

(Compound A)

To a 100-mL flask equipped with a thermometer, a stirrer, a nitrogen conduit, and a reflux condenser, 1-vinylimidazole (10.0 g) and water 30 g were fed, and 2,2′1-azobis{2-methyl-N-(2-hydroxyethyl)-propionamide} (0.61 g) was added to the mixture. The mixture was stirred well for dissolution of components, followed by elevating the temperature to 100° C. under mixing in a nitrogen atmosphere. After maintenance of the mixture at 100° C. for three hours, a solution (20.0 g) of 2,2′-azobis{2-methyl-N-(2-hydroxyethyl)-propionamide} (0.61 g) dissolved in water was further added to the mixture, and reaction was continued for three hours. The reaction mixture was cooled to room temperature, thereby forming about 60 g of clear brown solution. Through GPC measurement, the product was found to have a mass average molecular mass (as reduced to polyethylene glycol) of 110,000 and a number average molecular mass of 27,000.

(Compound B)

To a 500-mL flask equipped with a thermometer, a stirrer, a nitrogen conduit, and a reflux condenser, 2-propanol (40 g) was fed and the temperature was elevated under nitrogen atmosphere while stirring to 75° C. Then a solution in which 1-vinylimidazole (46.31 g) and N-vinyl pyrrolidone (43.69 g) were dissolved in 2-propanol (78 g) (hereinafter referred to as “a monomer solution”) and a solution of dimethyl-2,2′-azobis(2-methylpropionate) (4.08 g) in 2-propanol (163.92 g) (hereinafter referred to as “initiator solution 1”) were added through a metering pump, respectively. The addition times were 4 hours for the monomer solution and 6 hours for the initiator solution 1. After the initiator solution 1 was added, the temperature of the reaction solution was elevated to the refluzing temperature (about 83° C.). Further a solution of dimethyl-2,2′-azobis(2-methylpropionate) (2.04 g) in 2-propanol (38.76 g) (hereinafter referred to as “initiator solution 2”) were added to the mixture and the reaction was continued for 7.5 hours. After the reaction solution was cooled to room temperature, a clear brawn solution (about 415 g) was obtained. The clear brawn solution was condensed through a rotary vacuum evaporator and dissolved in water, which was repeated twice, to replace the solvent from 2-propanol to water. Through GPC measurement, the product was found to have a mass average molecular mass (as reduced to polyethylene glycol) of 10,500 and a number average molecular mass of 4,700.

(Compound C)

To a 500-mL flask equipped with a thermometer, a stirrer, a nitrogen conduit, and a reflux condenser, 2-propanol (40 g) was fed and the temperature was elevated under nitrogen atmosphere while stirring to a refluxing temperature (about 83° C.). Then a solution in which 1-vinylimidazole (46.31 g) and N-vinyl pyrrolidone (43.69 g) were dissolved in 2-propanol (78 g) (hereinafter referred to as “a monomer solution”) and a solution of dimethyl-2,2′-azobis(2-methylpropionate) (0.82 g) in 2-propanol (167.18 g) (hereinafter referred to as “initiator solution 1”) were added through a metering pump, respectively. The addition times were 4 hours for the monomer solution and 7 hours for the initiator solution 1. After the initiator solution 1 was added, the reaction was continued for 1 hour. Then a solution of dimethyl-2,2′-azobis(2-methylpropionate) (0.21 g) in 2-propanol (6.59 g) (hereinafter referred to as “initiator solution 2”) were added to the mixture and the reaction was further continued for 5 hours. After the reaction solution was cooled to room temperature, a clear brawn solution (about 380 g) was obtained. The clear brawn solution was condensed through a rotary vacuum evaporator and dissolved in water, which was repeated twice, to replace the solvent from 2-propanol to water. Through GPC measurement, the product was found to have a mass average molecular mass (as reduced to polyethylene glycol) of 14,200 and a number average molecular mass of 5,800.

(Compound D)

To a 500-mL flask equipped with a thermometer, a stirrer, a nitrogen conduit, and a reflux condenser, n-propanol (30 g) was fed and the temperature was elevated under nitrogen atmosphere while stirring to a refluxing temperature (about 98° C.). Then a solution in which 1-vinylimidazole (15.72 g), N-vinyl pyrrolidone (74.28 g) and 2-mercapto ethanol (0.066 g) were dissolved in n-propanol (29.93 g) (hereinafter referred to as “a monomer solution”) and a solution of dimethyl-2,2′-azobis(2-methylpropionate) (0.77 g) in n-propanol (215.23 g) (hereinafter referred to as “initiator solution 1”) were added through a metering pump, respectively. The addition times were 4 hours for both the monomer solution and the initiator solution 1. After the monomer solution and the initiator solution 1 were added, the reaction was continued for 1 hour. Then a solution of dimethyl-2,2′-azobis(2-methylpropionate) (0.77 g) in n-propanol (14.63 g) (hereinafter referred to as “initiator solution 2”) were added to the mixture and the reaction was further continued for 5 hours. After the reaction solution was cooled to room temperature, a clear brawn solution (about 380 g) was obtained. The clear brawn solution was condensed through a rotary vacuum evaporator and dissolved in water, which was repeated twice, to replace the solvent from 2-propanol to water. Through GPC measurement, the product was found to have a mass average molecular mass (as reduced to polyethylene glycol) of 5,500 and a number average molecular mass of 2,900.

(Compound E)

The same procedures as for synthesizing compound D were repeated, provided that the monomer solution was a solution of 1-vinylimidazole (59.76 g), N-vinyl pyrrolidone (30.24 g) and α-methylstyrene dimer (1.07 g) were dissolved in n-propanol (76.9 g); the initiator solution 1 was a solution of dimethyl-2,2′-azobis(2-methylpropionate) (1.25 g) in n-propanol (166.75 g); the initiator solution 2 was a solution of dimethyl-2,2′-azobis(2-methylpropionate) (0.42 g) in n-propanol (7.94 g); and the addition of the initiator was repeated three times. The other procedures were the same as those of synthesizing compound D. Through GPC measurement, the product was found to have a mass average molecular mass (as reduced to polyethylene glycol) of 9,300 and a number average molecular mass of 4,500.

As shown in Tables 2-1 to 2-5, in all Examples substantially no etching occurred. Thus, the polishing compositions according to the present invention attained remarkably excellent dishing prevention and erosion prevention characteristics. In contrast, polishing compositions of Comparative Examples 1 to 3 containing no phosphate ester did not suppress dishing, and erosion characteristics were unsatisfactory.

TABLE 1-1

| | | Ex. No. | | | | | | |
|---|---|---|---|---|---|---|---|---|
| | | 1 | 2 | 3 | 4 | 5 | 6 | 7 |
| C ≧ 6 Alkyl | Polyoxyethylene | 0.05 | 0.1 | 0.01 | 0.03 | 0.03 | | 0.03 |
| phosphate | sec-alkyl ether | | | | | | | |
| | phosphate | | | | | | | |
| | Lauryl phosphate | | | | | | 0.01 | |
| | Polyoxyethylene | | | | | | | |
| | octyl phosphate | | | | | | | |
| | Polyoxyethylene | | | | | | | |
| | oleyl phosphate | | | | | | | |
| | Polyoxyethylene | | | | | | | |
| | lauryl phosphate | | | | | | | |
| Etchant | Oxalic acid | 0.5 | 0.5 | 0.5 | 0.5 | 0.5 | 0.5 | 0.5 |
| | Lactic acid | | | | | | | |
| | Sulfuric acid | | | | | | | |
| | NH₃ | 0.22 | 0.22 | 0.25 | 0.25 | 0.28 | 0.28 | 0.28 |
| | Ethylene diamine | | | | | | | |
| | H₂O₂ | | | 0.5 | 0.5 | | | |
| | APS | 1 | 1 | | | 1 | 1 | 1 |
| | Potassium | | | | | | | |
| | hypochlorite | | | | | | | |
| Abrasive | Colloidal silica A | | 0.5 | 0.5 | 0.5 | 0.5 | 0.5 | 0.5 |
| | Colloidal silica B | | | | | | | |
| | Colloidal silica C | | | | | | | |
| Surfactant | DBS | | | 0.07 | 0.07 | 0.07 | 0.07 | 0.07 |
| | Polyoxyethylene | | | | | | | |
| | lauryl ether | | | | | | | |
| Compound of ≧2 | VPI55K18P | | | | 0.05 | 0.05 | 0.05 | |
| azole moieties | Compound A | | | | | | | 0.025 |
| | SakalanHP56 | | | | | | | |
| | Compound B | | | | | | | |
| | Compound C | | | | | | | |
| | Compound D | | | | | | | |
| | Compound E | | | | | | | |
| Amino acid | Norleucine | | | | | | | |
| | Alanine | | | | | | | |
| | Serine | | | | | | | |
| Compound of one | BTA | | | | | | | |
| azole moiety | Benzimidazol | | | | | | | |
| C ≧ 6 Alkyl | Oleic acid | | | | | | | |
| fatty acid | | | | | | | | |

| | | | | | | | |
|---|---|---|---|---|---|---|---|
| pH | 8 | 8 | 9 | 9 | 9 | 9 | 9 |

TABLE 1-2

| | | Ex. No. | | | | | | |
|---|---|---|---|---|---|---|---|---|
| | | 8 | 9 | 10 | 11 | 12 | 13 | 14 |
| C ≧ 6 Alkyl | Polyoxyethylene | 0.007 | 0.03 | 0.03 | 0.03 | | | |
| phosphate | sec-alkyl ether | | | | | | | |
| | phosphate | | | | | | | |
| | Lauryl phosphate | | | | | | | |
| | Polyoxyethylene | | | | | 0.08 | | |
| | octyl phosphate | | | | | | | |
| | Polyoxyethylene | | | | | | 0.08 | |
| | oleyl phosphate | | | | | | | |
| | Polyoxyethylene | | | | | | | 0.03 |
| | lauryl phosphate | | | | | | | |
| Etchant | Oxalic acid | | 0.5 | 0.5 | 0.5 | 0.5 | 0.5 | 0.5 |
| | Lactic acid | 1 | | | | | | |
| | Sulfuric acid | | | | | | | |
| | NH₃ | 0.28 | 0.25 | 0.25 | 0.25 | 0.28 | 0.28 | 0.28 |
| | Ethylene diamine | | | | | | | |
| | H₂O₂ | | 0.5 | 0.5 | 0.5 | | | |
| | APS | 1 | | | | 1 | 1 | 1 |
| | Potassium | | | | | | | |
| | hypochlorite | | | | | | | |
| Abrasive | Colloidal silica A | 0.5 | 0.5 | 0.5 | 0.5 | 0.5 | 0.5 | 1 |
| | Colloidal silica B | | | | | | | |
| | Colloidal silica C | | | | | | | |
| Surfactant | DBS | 0.05 | 0.07 | 0.07 | 0.07 | 0.07 | 0.07 | 0.07 |
| | Polyoxyethylene | | | | | | | |
| | lauryl ether | | | | | | | |
| Compound of ≧2 | VPI55K18P | 0.05 | 0.05 | 0.05 | 0.05 | 0.05 | 0.05 | 0.05 |
| azole moieties | Compound A | | | | | | | |
| | SakalanHP56 | | | | | | | |
| | Compound B | | | | | | | |
| | Compound C | | | | | | | |
| | Compound D | | | | | | | |
| | Compound E | | | | | | | |
| Amino acid | Norleucine | | 0.01 | | | | | |
| | Alanine | | | | | | | |
| | Serine | | | | | | | |
| Compound of one | BTA | | | 0.002 | | | | |
| azole moiety | Benzimidazol | | | | | | | |
| C ≧ 6 Alkyl | Oleic acid | | | | 0.01 | | | |
| fatty acid | | | | | | | | |

| | | | | | | | |
|---|---|---|---|---|---|---|---|
| pH | 9 | 9 | 9 | 9 | 9 | 9 | 9 |

TABLE 1-3

| | | Ex. No. | | | | | | |
|---|---|---|---|---|---|---|---|---|
| | | 15 | 16 | 17 | 18 | 19 | 20 | 21 |
| C ≧ 6 Alkyl | Polyoxyethylene | 0.03 | 0.03 | 0.03 | 0.03 | 0.03 | 0.03 | 0.03 |
| phosphate | sec-Alkyl ether | | | | | | | |
| | phosphate | | | | | | | |
| | Lauryl phosphate | | | | | | | |
| | Polyoxiethylene | | | | | | | |
| | octyl phosphate | | | | | | | |
| | Polyoxiethylene | | | | | | | |
| | oleyl phosphate | | | | | | | |
| | Polyoxiethylene | | | | | | | |
| | lauryl phosphate | | | | | | | |
| Etchant | Oxalic acid | 0.3 | 0.3 | 0.5 | 0.4 | 0.35 | 0.5 | 0.5 |
| | Lactic acid | | | | | | | |
| | Sulfuric acid | | | | 0.75 | 0.38 | | |
| | NH₃ | 0.28 | 0.28 | 0.28 | 0.58 | 0.42 | 0.28 | 0.28 |
| | Ethylene diamine | | | | | | | |
| | H₂O₂ | | | | 0.5 | 0.5 | | |
| | APS | 1 | 1 | 1 | | | 1 | |
| | Potassium | | | | | | | 0.5 |
| | hypochlorite | | | | | | | |
| Abrasive | Colloidal silica A | 1 | 1 | 1 | 1 | 1 | 0.5 | 0.5 |
| | Colloidal silica B | | | | | | | |
| | Colloidal silica C | | | | | | | |
| Surfactant | DBS | 0.07 | 0.07 | 0.07 | 0.07 | 0.07 | 0.07 | 0.07 |
| | Polyoxyethylene | | | | | | | |
| | lauryl ether | | | | | | | |
| Compound of ≧2 | VPI55K18P | 0.05 | 0.05 | 0.07 | 0.05 | 0.05 | 0.05 | 0.05 |
| azole moieties | Compound A | | | | | | | |
| | SakalanHP56 | | | | | | | |
| | Compound B | | | | | | | |
| | Compound C | | | | | | | |
| | Compound D | | | | | | | |
| | Compound E | | | | | | | |
| Amino acid | Norleucine | | | | | | | |
| | Alanine | | | 0.05 | | | | |
| | Serine | | 0.1 | | | | | |
| Compound of one | BTA | | | | | | | |
| azole moiety | Benzimidazol | | | | | | | |
| C ≧ 6 Alkyl | Oleic acid | 0.03 | | 0.03 | | 0.05 | | |
| fatty acid | | | | | | | | |

| | | | | | | | |
|---|---|---|---|---|---|---|---|
| pH | 9 | 9 | 9 | 9 | 9 | 9 | 9 |

TABLE 1-4

| | | Ex. No. | | | | | | |
|---|---|---|---|---|---|---|---|---|
| | | 22 | 23 | 24 | 25 | 26 | 27 | 28 |
| C ≧ 6 Alkyl | Polyoxyethylene | 0.03 | 0.03 | 0.03 | 0.03 | 0.03 | 0.03 | 0.03 |
| phosphate | sec-alkyl ether | | | | | | | |
| | phosphate | | | | | | | |
| | Lauryl phosphate | | | | | | | |
| | Polyoxyethylene | | | | | | | |
| | octyl phosphate | | | | | | | |
| | Polyoxyethylene | | | | | | | |
| | oleyl phosphate | | | | | | | |
| | Polyoxyethylene | | | | | | | |
| | lauryl Phosphate | | | | | | | |
| Etchant | Oxalic acid | 0.5 | 0.5 | 0.5 | 0.5 | 0.5 | 0.5 | 0.5 |
| | Lactic acid | | | | | | | |
| | Sulfuric acid | | | | | | | |
| | NH₃ | 0.33 | 0.33 | 0.33 | 0.33 | 0.33 | 0.33 | 0.33 |
| | Ethylene diamine | | | | | | | |
| | H₂O₂ | | | | | | | |
| | APS | 1 | 1 | 1 | 1 | 1 | 1 | 1 |
| | Potassium | | | | | | | |
| | hypochlorite | | | | | | | |
| Abrasive | Colloidal silica A | | | | | | | |
| | Colloidal silica B | 0.75 | 1 | 0.75 | 1 | 1.5 | 0.75 | 0.75 |
| | Colloidal silica C | | | | | | | |
| Surfactant | DBS | 0.07 | 0.07 | 0.07 | 0.07 | 0.07 | 0.07 | 0.07 |
| | Polyoxyethylene | | | | | | | |
| | lauryl ether | | | | | | | |
| Compound of ≧2 | VPI55K18P | 0.05 | 0.05 | | | | | |
| azole moieties | Compound A | | | | | | | |
| | SakalanHP56 | | | 0.005 | | | | |
| | Compound B | | | | 0.01 | | | |
| | Compound C | | | | | 0.01 | | |
| | Compound D | | | | | | 0.05 | |
| | Compound E | | | | | | | 0.05 |
| Amino acid | Norleucine | | | | | | | |
| | Alanine | | | | | | | |
| | Serine | | | | | | | |
| Compound of one | BTA | | | | | | | |
| azole moiety | Benzimidazol | 0.005 | 0.005 | 0.005 | 0.005 | 0.005 | 0.005 | 0.005 |
| C ≧ 6 Alkyl | Oleic acid | 0.03 | 0.03 | 0.03 | 0.03 | 0.03 | 0.03 | 0.03 |
| fatty acid | | | | | | | | |

| | | | | | | | |
|---|---|---|---|---|---|---|---|
| pH | 9 | 9 | 9 | 9 | 9 | 9 | 9 |

TABLE 1-5

| | | No. | | | | |
|---|---|---|---|---|---|---|
| | | | | Com. | Com. | Com. |
| | | Ex. 29 | Ex. 30 | Ex. 1 | Ex. 2 | Ex. 3 |
| C ≧ 6 Alkyl | Polyoxy- | 0.03 | 0.03 | | | |
| phosphate | ethylene | | | | | |
| | sec-Alkyl | | | | | |
| | ether | | | | | |
| | phosphate | | | | | |
| | Lauryl | | | | | |
| | phosphate | | | | | |
| | Polyoxy- | | | | | |
| | ethylene | | | | | |
| | octyl | | | | | |
| | phosphate | | | | | |
| | Polyoxy- | | | | | |
| | ethylene | | | | | |
| | oleyl | | | | | |
| | phosphate | | | | | |
| | Polyoxy- | | | | | |
| | ethylene | | | | | |
| | lauryl | | | | | |
| | phosphate | | | | | |
| Etchant | Oxalic acid | 0.5 | 0.5 | 0.5 | 0.5 | 0.5 |
| | Lactic acid | | | | | |
| | Sulfuric | | | | | |
| | acid | | | | | |
| | NH₃ | 0.33 | 0.33 | 0.22 | 0.22 | 0.25 |
| | Ethylene | 0.01 | | | | |
| | diamine | | | | | |
| | H₂O₂ | | | 0.5 | 0.5 | 0.5 |
| | APS | 1 | 1 | | | |
| | Potassium | | | | | |
| | hypochlorite | | | | | |
| Abrasive | Colloidal | | | | 0.5 | 0.5 |
| | silica A | | | | | |
| | Colloidal | 1 | | | | |
| | silica B | | | | | |
| | Colloidal | | 1 | | | |
| | silica C | | | | | |
| Surfactant | DBS | 0.07 | 0.07 | | | 0.05 |
| | Polyoxy- | | | | | 0.025 |
| | ethylene | | | | | |
| | lauryl ether | | | | | |
| Compound | VPI55K18P | 0.03 | 0.05 | | | |
| of ≧2 | Compound A | | | | | |
| azole | SakalanHP56 | | | | | |
| moieties | Compound B | | | | | |
| | Compound C | | | | | |
| | Compound D | | | | | |
| | Compound E | | | | | |
| Amino acid | Norleucine | | | | | |
| | Alanine | | | | | |
| | Serine | | | | | |
| Compound | BTA | | | 0.002 | 0.002 | |
| of one | Benzimidazol | 0.01 | 0.005 | | | |
| azole | | | | | | |
| moiety | | | | | | |
| C ≧ 6 Alkyl | Oleic acid | 0.03 | 0.03 | | | |
| fatty acid | | | | | | |

| | | | | | |
|---|---|---|---|---|---|
| pH | 9 | 9 | 8 | 8 | 9 |

TABLE 2

| | Ex. No. | | | | | | |
|---|---|---|---|---|---|---|---|
| | 1 | 2 | 3 | 4 | 5 | 6 | 7 |
| Polishing rate | 411 | 608 | 473 | 610 | 858 | 792 | 874 |
| (nm/min) | | | | | | | |
| Dishing (nm) | 217 | 194 | 105 | 111 | 72 | 81 | 85 |
| Erosion (nm) | 3 | 3 | 3 | 5 | 7 | 5 | 5 |
| Etchability | 0 | 0 | 0 | 0 | 0 | 0 | 0 |
| (nm/min) | | | | | | | |
| | Ex. No. | | | | | | |
| | 8 | 9 | 10 | 11 | 12 | 13 | 14 |
| Polishing rate | 434 | 589 | 516 | 541 | 758 | 866 | 583 |
| (nm/min) | | | | | | | |
| Dishing (nm) | 93 | 104 | 54 | 81 | 78 | 229 | 80 |
| Erosion (nm) | 4 | 7 | 1 | 5 | 0 | 5 | 7 |
| Etchability | 0 | 0 | 0 | 0 | 0 | 0 | 0 |
| (nm/min) | | | | | | | |
| | Ex. No. | | | | | | |
| | 15 | 16 | 17 | 18 | 19 | 20 | 21 |
| Polishing rate | 879 | 805 | 742 | 1221 | 797 | 550 | 589 |
| (nm/min) | | | | | | | |
| Dishing (nm) | 85 | 52 | 90 | 79 | 37 | 60 | 43 |
| Erosion (nm) | 0 | 19 | 5 | 0 | 17 | 5 | 1 |
| Etchability | 0 | 0 | 0 | 0 | 0 | 0 | 0 |
| (nm/min) | | | | | | | |
| | Ex. No. | | | | | | |
| | 22 | 23 | 24 | 25 | 26 | 27 | 28 |
| Polishing rate | 751 | 710 | 948 | 821 | 641 | 882 | 838 |
| (nm/min) | | | | | | | |
| Dishing (nm) | 16 | 17 | 15 | 11 | 9 | 37 | 15 |
| Erosion (nm) | 1 | 7 | 5 | 2 | 2 | 8 | 4 |
| Etchability | 0 | 0 | 0 | 0 | 0 | 0 | 0 |
| (nm/min) | | | | | | | |

| | Ex. No. | | | | |
|---|---|---|---|---|---|
| | | | Comp. | Comp. | Comp. |
| | 29 | 30 | Ex. 1 | Ex. 2 | Ex. 3 |
| Polishing rate | 783 | 850 | 420 | 531 | 620 |
| (nm/min) | | | | | |
| Dishing (nm) | 17 | 19 | 492 | 495 | 490 |
| Erosion (nm) | 10 | 6 | 9 | 23 | 5 |
| Etchability | 0 | 0 | 0 | 0 | 0 |
| (nm/min) | | | | | |

### INDUSTRIAL APPLICABILITY

According to the present invention, the polishing composition containing a phosphate ester can reduce dishing of metal film, in particular copper film during polishing thereof. Dishing can be further reduced by use of a polishing composition further containing, in combination, at least one member selected from among a surfactant, a compound having two or more azole moieties, an amino acid, a compound having one azole moiety, and a fatty acid having a C≧6 alkyl group. According to the polishing method employing the polishing composition of the present invention, and to the method for producing a substrate, a substrate having a remarkably flat surface can be readily produced.

1. A polishing composition for polishing a metal film provided on a substrate having trenches such that the metal film fills the trenches, so as to provide a planarized surface, wherein the composition comprises water, a phosphate ester having a C≧6 carbon atom alkyl group in its molecule, and an etchant for the metal, and has a pH of 5 to 11.

2. The polishing composition according to claim 1, wherein said phosphate ester is a phosphate ester having a C6 to C22 alkyl group in its molecule.

3. The polishing composition according to claim 1, wherein the content of said phosphate ester is in a range of 0.0001 to 2 mass %.

4. The polishing composition according to claim 1, wherein said etchant comprises an acid and/or a base, and an oxidizing agent.

5. The polishing composition according to claim 4, wherein the content of said an acid and/or a base is in range of 0.01 to 10 mass %.

6. The polishing composition according to claim 4, wherein the content of said oxidizing agent is in range of 0.01 to 30 mass %.

7. The polishing composition according to claim 1, which further comprises abrasive.

8. The polishing composition according to claim 7, wherein the content of said abrasive is in range of 30 mass % or less.

9. The polishing composition according to claim 1, which further comprises a surfactant.

10. The polishing composition according to claim 9, wherein the content of said surfactant is in range of 5 mass % or less.

11. The polishing composition according to claim 1, which further comprises a compound having two or more azole moieties in its molecule.

12. The polishing composition according to claim 11, wherein the content of said compound having two or more azole moieties in its molecule is in range of 0.001 to 1 mass %.

13. The polishing composition according to claim 1, which further comprises an amino acid.

14. The polishing composition according to claim 13, wherein the content of said amino acid is in range of 0.001 to 10 mass %.

15. The polishing composition according to claim 1, which further comprises a compound having one azole moiety in its molecule.

16. The polishing composition according to claim 15, wherein the content of said compound having one azole moiety in its molecule is in range of 0.001 to 5 mass %.

17. The polishing composition according to claim 1, which further comprises a fatty acid having a six or more carbon atom alkyl group in its molecule.

18. The polishing composition according to claim 17, wherein the content of said fatty acid having a C≧6 carbon atom alkyl group in its molecule is in range of 0.001 to 5 mass %.

19. The polishing composition according to claim 4, where said acid is an inorganic acid or carboxylic acid.

20. The polishing composition according to claim 4, wherein said acid is at least one species selected from the group consisting of sulfuric acid, phosphoric acid, phosphonic acid, nitric acid, formic acid, acetic acid, propionic acid, butyric acid, valeric acid, 2-methylburyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid (hydroxyacetic acid), salicylic acid, glyceric acid, oxalic acid, malonic acid, succinic acid, glutaric acid, adipic acid, pimelic acid, maleic acid, phthalic acid, malic acid, tartaric acid, citric acid, lactic acid, nicotic acid, quinaldinic acid, and anthranilic acid.

21. (canceled)

22. The polishing composition according to claim 4, wherein said base is at least one species selected from the group consisting of ammonia; sodium hydroxide; potassium hydroxide; potassium carbonate; potassium hydrogencarbonate; ammonium hydrogencarbonate; methylamine, ethylamine, propylamine, isopropylamine, butylamine, isobutylamine, t-butylamine, amylamine, allylamine; 2-ethylhexylamine; cyclohexylamine, benzylamine, furfurylamine; o-aminophenol, ethanolamine, 3-amino-1-propanol, 2-amino-1-propanol; ethylenediamine, diethylenetriamine, triethylenetetramine, tetraethylenepentamine, pentaethylenehexamine, o-phenylenediamine, trimethylenediamine, 1,2-diaminopropane, 2,2-diamino-di-n-propylamine, 2-methyl-2-(2-benzylthioethyl)ethylenediamine, 1,5-diamino-3-pentanol, 1,3-diamino-2-propanol, xylenediamine, and bisaminopropylpolyalkylene ether; polyallylamine and polyethyleneimine.

23. The polishing composition according to claim 4, wherein said oxidizing agent is at least one species selected from the group consisting of oxygen, hydrogen peroxide, ozone, alkyl peroxides, peracids, permanganate salts, persulfate salts, polyoxo acids, hypochlorite salts, and periodate salts.

24. The polishing composition according to claim 8, wherein said abrasive is formed of at least one species selected from the group consisting of silica, cerium oxide, aluminum oxide, aluminum hydroxide, titanium dioxide, and organic abrasive.

25. The polishing composition according to claim 10, wherein said surfactant is at least one species selected from the group consisting of anionic surfactants, cationic surfactants, nonionic surfactants, and ampholytic surfactants.

26. The polishing composition according to claim 10, wherein said surfactant is an alkylaromatic-sulfonic acid or a salt thereof.

27. The polishing composition according to claim 12, wherein said compound having two or more azole moieties in its molecule is an azole polymer having a vinyl group.

28. The polishing composition according to claim 12, wherein said compound having two or more azole moieties in its molecule is a polymer having a mass average molecular mass of 2,000 to 500,000.

29. The polishing composition according to claim 13, wherein said amino acid is at least one species selected from the group consisting of glycine, alanine, β-alanine, 2-aminobutyric acid, norvaline, valine, leucine, norleucine, isoleucine, allo-isoleucine, phenylalanine, proline, sarcosine, ornithine, lysine, taurine, serine, threonine, allo-threonine, homoserine, tyrosine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxy-lysine, creatine, kynurenine, histidine, 1-methyl-histidine, 3-methyl-histidine, ergothioneine, and tryptophan.

30. The polishing composition according to claim 15, wherein said compound having one azole moiety in its molecule is at least one species selected from the group consisting of benzimidazole-2-thiol, 2-[2-(benzothiazolyl)]thiopropionic acid, 2-[2-(benzothiazolyl)]thiobutyric acid, 2-mercaptobenzothiazole, 1,2,3-triazole, 1,2,4-triazole, 3-amino-1H-1,2,4-triazole, benzotriazole, 1-hydroxybenzotriazole, 1-dihydroxypropylbenzotriazole, 2,3-dicarboxypropylbenzotriazole, 4-hydroxybenzotriazole, 4-carboxyl-1H-benzotriazole, 4-methoxycarbonyl-1H-benzotriazole, 4-butoxycarbonyl-1H-benzotriazole, 4-octyloxycarbonyl-1H-benzotriazole, 5-hexylbenzotriazole, N-(1,2,3-benzotriazolyl-1-methyl)-N-(1,2,4-triazolyl-1-methyl)-2-ethylhexylamine, tolyltriazole, naphthotriazole, benzimidazole, tetrazole, hydroxybenzotriazole, and carboxybenzotriazole.

31. A composition which forms the polishing composition as set forth in claim 1 by dilution.

32. A kit comprising a plurality of compositions, which forms the polishing composition as set forth in claim 1 by (i) mixing or (ii) mixing and diluting said plurality of compositions.

33. A polishing method, characterized by comprising polishing, by use of the polishing composition as recited in claim 1, a metal film provided on a substrate having trenches such that the metal film fills the trenches so as to provide a planarized surface.

34. The polishing composition according to claim 33, wherein said metal film is of copper or an alloy containing copper.

35. The polishing composition according to claim 34, wherein said metal film is stacked with at least two layers: a barrier layer and a metal wiring layer.

36. The polishing composition according to claim 35, wherein said barrier layer is formed of at least one species selected from the group consisting of tantalum, tantalum alloy, tantalum nitride, titanium, and titanium alloy.

37. A method for using the composition as set forth in claim 31.

38. A method for using the kit as set forth in claim 32 as a composition for transportation or storage.
